(19) United States
(12) Patent Application Publication
(10) Pub. No.: US 2024/0153921 A1
(43) Pub. Date: May 9, 2024

(54) ELECTRONIC PACKAGE INCLUDING IC DIES ARRANGED IN INVERTED RELATIVE ORIENTATIONS

(71) Applicant: Microchip Technology Incorporated, Chandler, AZ (US)

(72) Inventors: Randy Yach, Phoenix, AZ (US); Paul Schimel, Algonquin, IL (US)

(73) Assignee: Microchip Technology Incorporated, Chandler, AZ (US)

(21) Appl. No.: 18/202,356

(22) Filed: May 26, 2023

Related U.S. Application Data
(60) Provisional application No. 63/422,068, filed on Nov. 3, 2022.

(51) Int. Cl. H01L 25/07; H01L 21/56; H01L 23/00; H01L 25/00

(52) U.S. Cl. CPC H01L 25/072; H01L 21/568; H01L 24/19; H01L 24/20; H01L 24/96; H01L 25/50; H01L 24/94; H01L 2224/19; H01L 2224/214; H01L 2224/215; H01L 2224/221; H01L 2224/224; H01L 2224/94; H01L 2224/96; H01L 2924/01022; H01L 2924/01029; H01L 2924/0132; H01L 2924/10272; H01L 2924/13091

(57) ABSTRACT

An electronic package includes a first integrated circuit (IC) die arranged in a first orientation, a second IC die arranged in a second orientation inverted relative to the first orientation, at least one upper conductive routing layer extending over the first IC die and second IC die, at least one lower conductive routing layer extending under the first IC die and second IC die, and a mold compound at least partially encapsulating the first IC die and the second IC die.

### RELATED PATENT APPLICATION

This application claims priority to commonly owned U.S. Provisional Patent Application No. 63/422,068 filed Nov. 3, 2022, the entire contents of which are hereby incorporated by reference for all purposes.

### TECHNICAL FIELD

The present disclosure relates to electronic packages, and more particularly to an electronic package including IC dies arranged in inverted relative orientations.

### BACKGROUND

The semiconductor industry continues to develop advanced packaging technologies, for example to reduce costs through improvements in yield, materials and production processes. For example, semiconductor manufacturers are developing various Panel Level Packaging (PLP) techniques for high-volume manufacturing on large panels (as compared with wafer-level manufacturing), often with wafer-level precision. PLP is commonly used for packaging field-programmable gate arrays (FPGA), CPU/GPU devices, power modules (for example silicon carbide (SiC) based power modules), baseband devices, and other electronic devices. One type of PLP is panel-level fan-out packaging, which applies the concept of “fanning out” die connections from the die's footprint, conventionally used in wafer-level processing, to panel-level manufacturing.

PLP manufacturing processes include “mold-first” processes, wherein a mold encapsulation is formed over IC die(s) prior to forming at least one metal redistribution layer (RDL) to electrically contact the IC die(s), and “RDL-first” processes, wherein at least one RDL is formed prior to mounting IC die(s) and forming a mold encapsulation.

There is a need for improved semiconductor packages and packaging processes, e.g., with small package size, low manufacturing cost, and/or improved performance of the packaged electronics.

### SUMMARY

An electronic package may include (a) at least one face-up IC die (e.g. MOSFET die), (b) at least one face-down IC die (e.g. MOSFET die), and (c) respective conductive routing structures on both the upper and lower sides of the face-up and face-down dies. Such electronic package may be referred to as a “double-sided electronic package.” In some examples double-sided electronic packages may be formed using a panel level packaging (PLP) process, e.g., wherein an array of double-sided electronic packages are formed on a common panel and then singulated to produce multiple discrete double-sided electronic packages.

One aspect provides an electronic package including a first integrated circuit (IC) die arranged in a first orientation, a second IC die arranged in a second orientation inverted relative to the first orientation, an upper conductive routing structure extending over the first IC die and second IC die, a lower conductive routing structure extending under the first IC die and second IC die, and an encapsulation structure at least partially encapsulating the first IC die and the second IC die.

In some examples, the electronic package comprises a panel level package (PLP).

In some examples, the first IC die arranged in the first orientation comprises a first Metal Oxide Silicon Field Effect Transistor (MOSFET) die arranged with (a) a first MOSFET gate connection pad and a first MOSFET source connection pad on an upper side of the first MOSFET die, and (b) a first MOSFET drain connection pad on a lower side of the first MOSFET die; and the second IC die arranged in the second orientation comprises a second MOSFET die arranged with (a) a second MOSFET drain connection pad on an upper side of the second MOSFET die and (b) a second MOSFET gate connection pad and a second MOSFET source connection pad on a lower side of the second MOSFET die.

In some examples, the upper conductive routing structure defines (a) a high voltage terminal connected to the second MOSFET drain connection pad on the upper side of the second MOSFET die and (b) a ground terminal connected to the first MOSFET source connection pad on the upper side of the first MOSFET die; and the lower conductive routing structure defines an output terminal connected to (a) the first MOSFET drain connection pad on the lower side of the first MOSFET die and (b) the second MOSFET source connection pad on the lower side of the second MOSFET die.

In some examples, the first IC die comprises a first silicon carbide (SiC) MOSFET, and the second IC die comprises a second SiC MOSFET.

In some examples, at least one of the upper conductive routing structure or the lower conductive routing structure comprises a redistribution layer (RDL).

In some examples, the upper conductive routing structure comprises multiple stacked upper redistribution layers (RDLs), and the lower conductive routing structure comprises multiple stacked lower RDLs.

In some examples, the upper conductive routing structure and the lower conductive routing structure comprise electroplated copper.

In some examples, at least one of the upper conductive routing structure or the lower conductive routing structure comprises a leadframe.

In some examples, the electronic package includes a third integrated circuit (IC) die arranged in the first orientation, and a fourth IC die arranged in the second orientation inverted relative to the first orientation, wherein the upper conductive routing structure extends over the first IC die, second IC die, third IC die, and fourth IC die, and wherein the lower conductive routing structure extends under the first IC die, second IC die, third IC die, and fourth IC die.

One aspect provides an electronic device including an electronic package. The electronic package includes a plurality of first Metal Oxide Silicon Field Effect Transistor (MOSFET) dies arranged in a first orientation, a plurality of second MOSFET dies arranged in a second orientation inverted relative to the first orientation, a first conductive routing structure including at least one first conductive routing layer extending over the plurality of first MOSFET dies and over the plurality of second MOSFET dies, and a second conductive routing structure including at least one second conductive routing layer extending under the plurality of first MOSFET dies and under the plurality of second MOSFET dies. The first conductive routing structure defines a first MOSFET drain connection structure connected to respective drain connection pads on the plurality of first MOSFET dies, a second MOSFET source connection structure connected to respective source connection pads on the plurality of second MOSFET dies, and a second MOSFET gate connection structure connected to respective gate connection pads on the plurality of second MOSFET dies. The second conductive routing structure defines a second MOSFET drain connection structure connected to respective drain connection pads on the plurality of second MOSFET dies, and a first MOSFET source connection structure connected to respective source connection pads on the plurality of first MOSFET dies.

In some examples, the electronic package comprising an encapsulation structure at least partially encapsulating the plurality of first MOSFET dies, the plurality of second MOSFET dies, the first conductive routing structure, and the second conductive routing structure.

In some examples, the electronic package comprising a first MOSFET gate connection structure connected to respective gate connection pads on the plurality of first MOSFET dies, the first MOSFET gate connection structure including at least one conductive element formed in the first conductive routing structure and at least one conductive element formed in the second conductive routing structure.

In some examples, the electronic device includes a busbar connected to the second MOSFET source connection structure and the first MOSFET drain connection structure.

In some examples, the electronic device includes a printed circuit board, wherein the second MOSFET drain connection structure and the first MOSFET source connection structure are mounted to respective electronics on the printed circuit board.

In some examples, the electronic device includes a printed circuit board, wherein the second MOSFET source connection structure, the first MOSFET drain connection structure, the first MOSFET gate connection structure, and the second MOSFET gate connection structure are mounted to respective electronics on the printed circuit board.

One aspect provides a method of forming an electronic package. A thermal release layer is formed on a carrier. A first IC die and a second IC die are arranged on the thermal release layer, the first IC die arranged in a first orientation, and the second IC die arranged in a second orientation inverted relative to the first orientation, wherein a first side of the first IC die and a second side of the second IC die face the carrier, and a second side of the first IC die and a first side of the second IC die face away from the carrier. A mold encapsulation is formed over the first IC die and second IC die. A first conductive routing structure is formed over the second side of the first IC die and the first side of the second IC die, the first conductive routing structure defining first conductive connections to respective contacts on the second side of the first IC die and the first side of the second IC die. The carrier is removed. A second conductive routing structure is formed on the first side of the first IC die and the second side of the second IC die, the second conductive routing structure defining second conductive connections to respective contacts on the first side of the first IC die and the second side of the second IC die.

In some examples, the method includes forming a first contact element on the first IC die prior to arranging the first IC die on the thermal release layer, wherein arranging the first IC die on the thermal release layer comprises arranging the first IC die with the first contact element facing the thermal release layer.

In some examples, the method includes forming a first contact element on the first IC die prior to arranging the first IC die on the thermal release layer, wherein forming the first conductive routing structure comprises forming at least one first conductive routing element in contact with the first contact element on the first IC die.

In some examples, the method includes forming a vertically-extending contact extending upwardly from the thermal release layer, wherein forming the second conductive routing structure includes forming a conductive connection between the vertically-extending contact and a respective contact on the first side of the first IC die.

In some examples, the method includes forming the vertically-extending contact extending upwardly from the thermal release layer prior to arranging the first IC die and the second IC die on the thermal release layer.

In some examples, the method includes forming a first vertically-extending contact and a second vertically-extending contact extending upwardly from the thermal release layer, wherein forming the second conductive routing structure includes forming (a) a first conductive connection between the first vertically-extending contact and a respective contact on the first side of the first IC die and (b) a second conductive connection between the second vertically-extending contact and a respective contact on the second side of the second IC die.

In some examples, the first IC die comprises a first MOSFET die, the second IC die comprises a second MOSFET die, and arranging the first IC die and the second IC die on the thermal release layer includes: (i) arranging the first IC die with (a) a first MOSFET gate connection pad and a first MOSFET source connection pad on the second side of the first IC die facing away from the carrier, and (b) a first MOSFET drain connection pad on the first side of the first IC die facing the carrier; and (ii) arranging the second IC die with (a) a second drain connection pad on the first side of the second IC die facing away from the carrier and (b) a second gate connection pad and a second source connection pad on the second side of the second IC die facing the carrier.

In some examples, forming the first conductive routing structure or forming the second conductive routing structure comprises forming a stack of multiple redistribution layers (RDLs).

In some examples, forming the first conductive routing structure or forming the second conductive routing structure comprises forming electroplated copper.

In some examples, forming the first conductive routing structure or forming the second conductive routing structure comprises attaching a leadframe.

### BRIEF DESCRIPTION OF THE DRAWINGS

Example aspects of the present disclosure are described below in conjunction with the figures, in which:

FIG. 1A shows a top view, and FIG. 1B shows a cross-sectional side view through line 1B-1B shown in FIG. 1A, of an example double-sided electronic package including a face-up IC die, a face-down IC die, and conductive routing layers extending above and below the face-up and face-down IC dies;

FIG. 2A shows a top view, and FIG. 2B shows a cross-sectional side view through line 2B-2B shown in FIG. 2A, of an example electronic device including an example double-sided electronic package;

FIGS. 3A-3Z are a series of cross-sectional side views showing an example method of forming an example double-sided electronic package; and

FIGS. 4A and 4B illustrate an example alternative process for forming vertically-extending contacts, e.g., for connecting respective elements of upper conductive routing layer(s) and lower conductive routing layer(s).

It should be understood the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

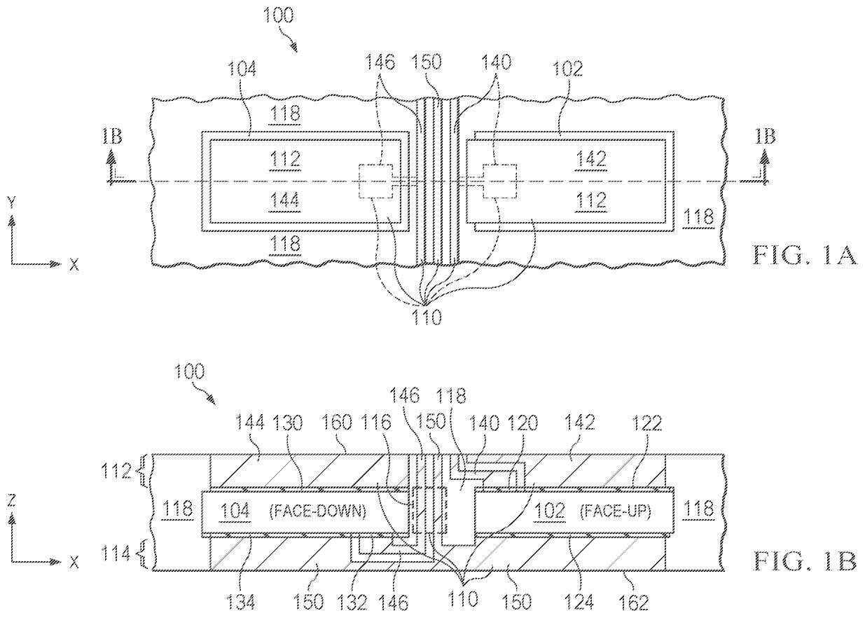

FIGS. 1A and 1B shows an example double-sided electronic package 100 (or simply electronic package 100, for convenience) including conductive routing layers above and below a pair of IC dies arranged inverted relative to each other. In particular, FIG. 1A shows a top view of the example electronic package 100, and FIG. 1B shows a cross-sectional side view through line 1B-1B shown in FIG. 1A.

The example electronic package 100 includes a first IC die 102 arranged in a first orientation and a second IC die 104 arranged in a second orientation inverted relative to the first orientation. The first orientation of the first IC die 102 and the second orientation of the second IC die 104 are discussed below, e.g., with reference to the positioning of respective source connection pads, gate connection pads, and drain connection pads of the first IC die 102 and second IC die 104.

The electronic package 100 may include a conductive routing structure 110 including (a) an upper conductive routing structure 112 extending over the first IC die 102 and second IC die 104, (b) a lower conductive routing structure 114 extending under the first IC die 102 and second IC die 104, and (c) an intermediate conductive routing structure 116 between the upper conductive routing structure 112 and lower conductive routing structure 114, e.g., to connect respective elements of the upper conductive routing structure 112 with respective elements of the lower conductive routing structure 114.

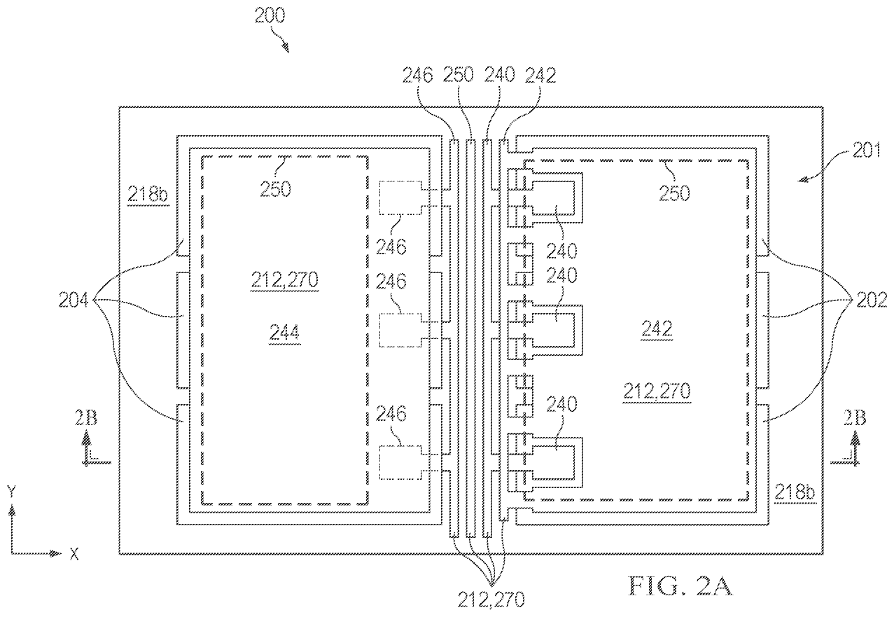

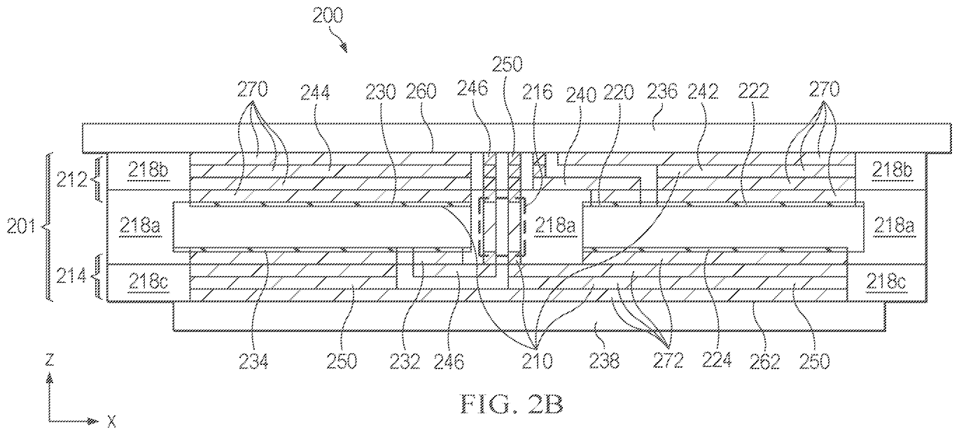

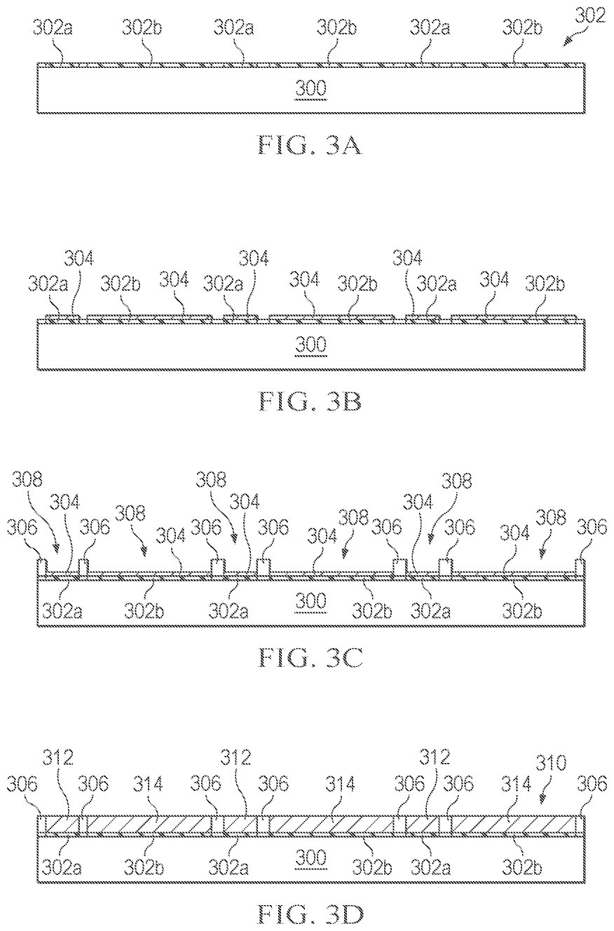

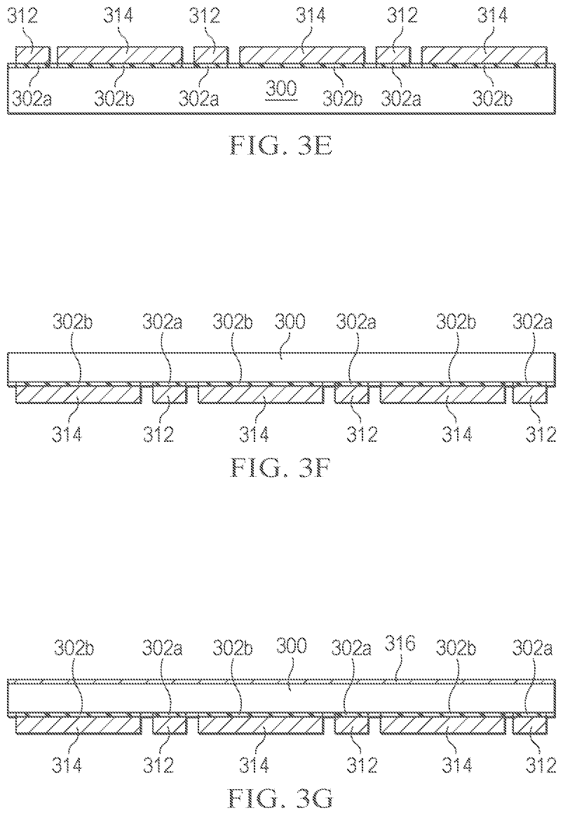

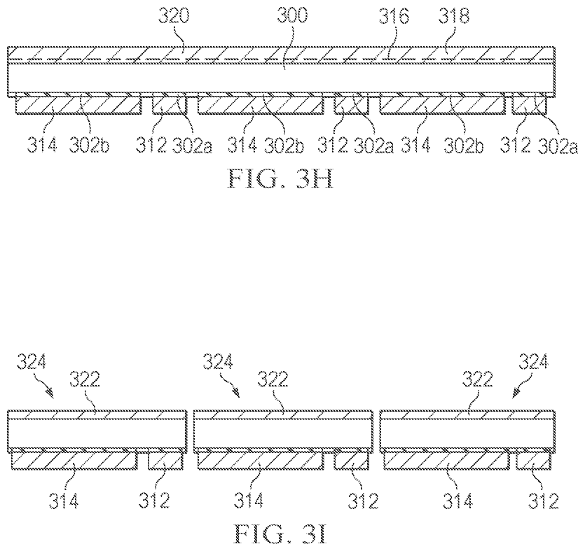

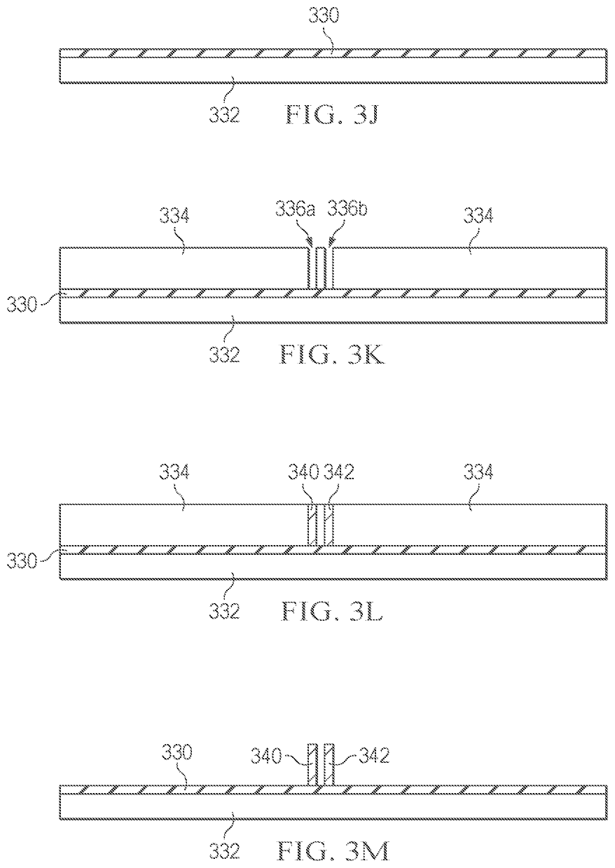

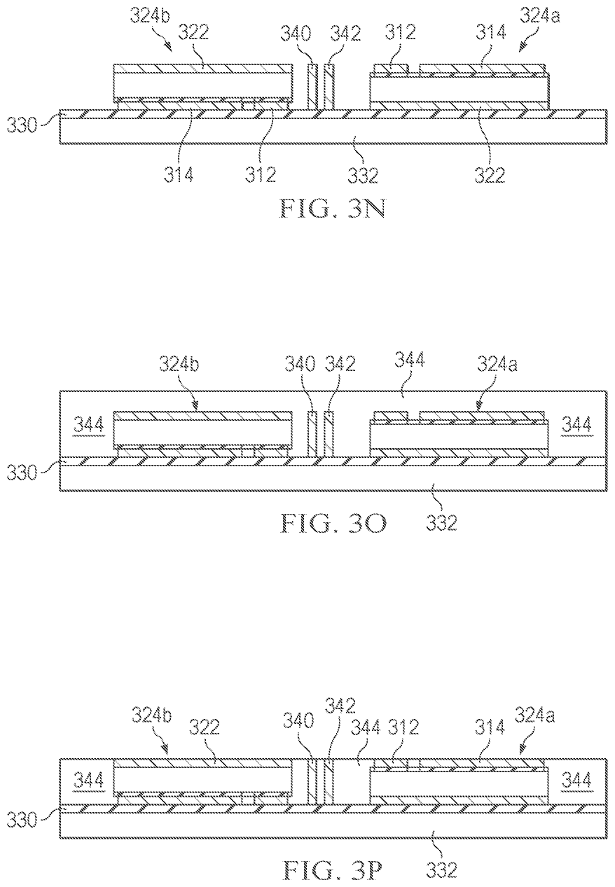

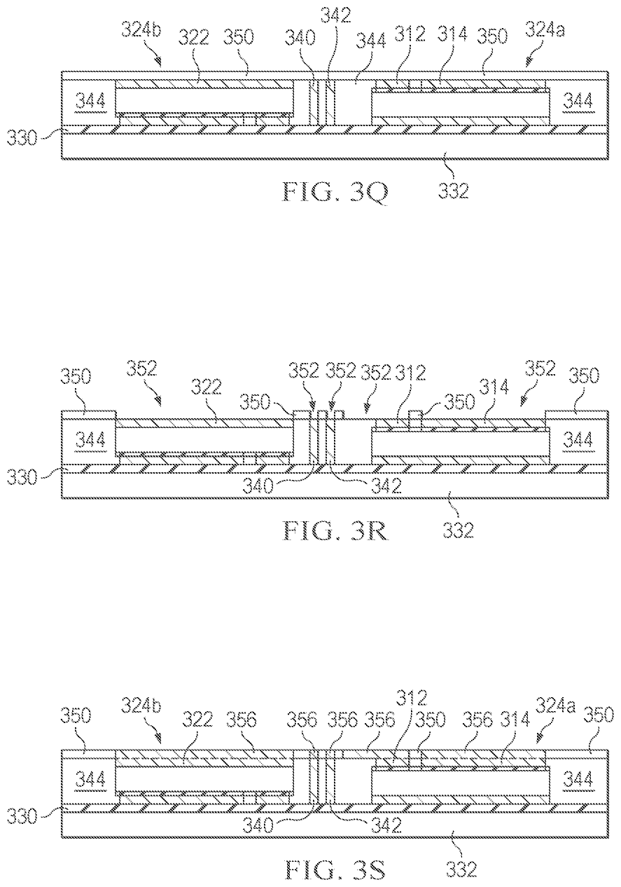

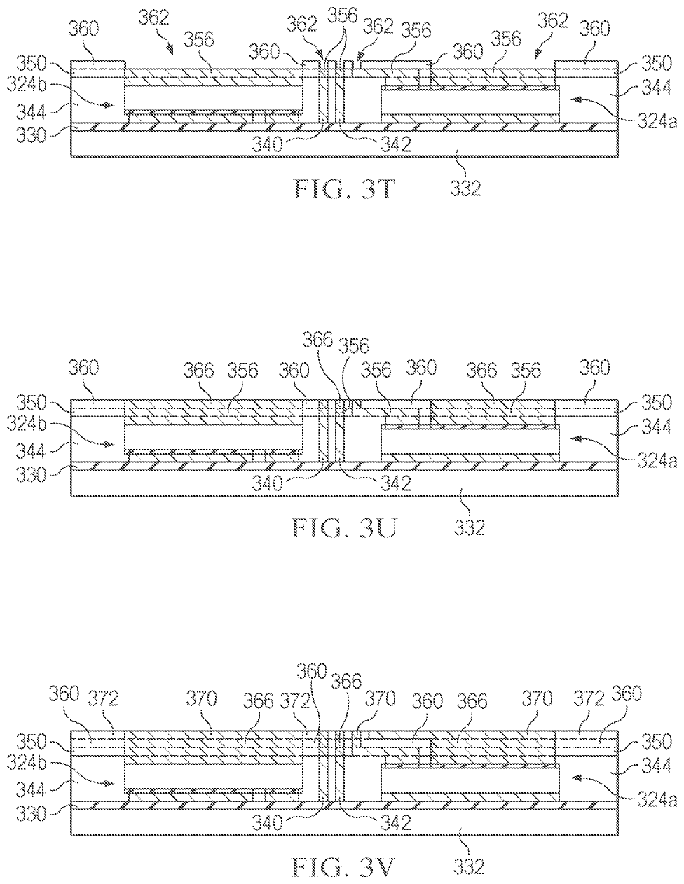

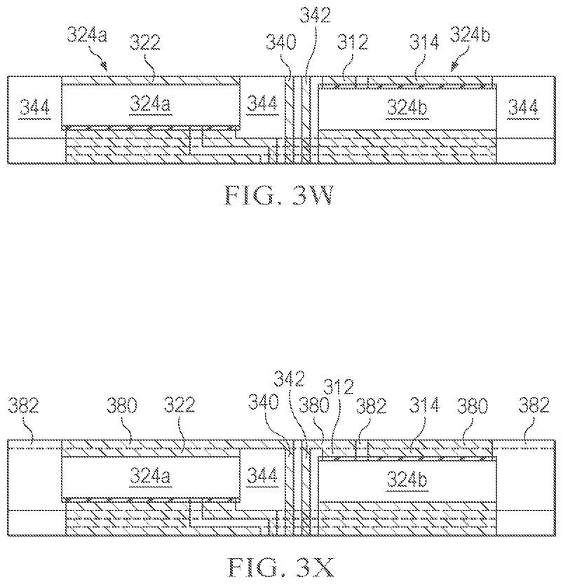

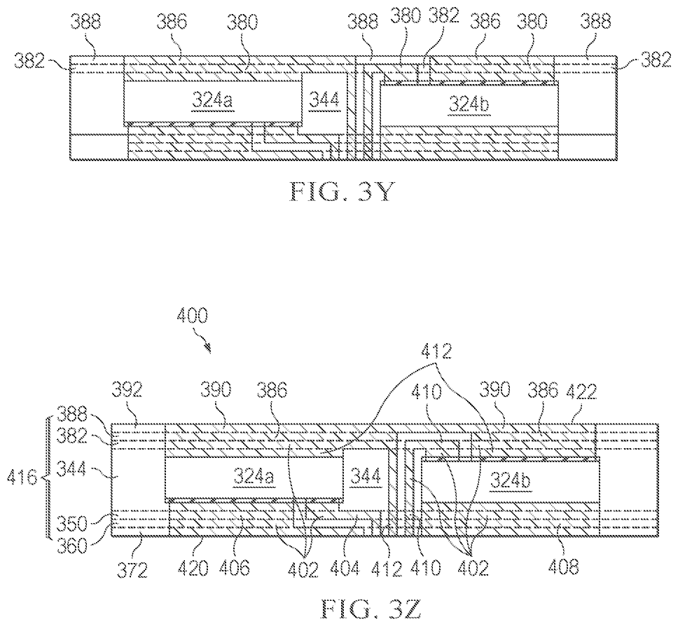

An encapsulation structure 118 at least partially encapsulates the first IC die 102 and second IC die 104. The encapsulation structure 118 may include one or multiple encapsulation regions, e.g., comprising an epoxy or other mold compound, a photosensitive material (e.g., polyimide (PI) or polyphenylene ester (POB)), or other insulating material or materials. In some examples, e.g., as discussed below with reference to FIGS. 2A-2B and FIGS. 3A-3Z, the encapsulation structure 118 includes (a) a mold compound region (e.g., comprising an epoxy) formed around the first IC die 102, second IC die 104, and intermediate conductive routing structure 116, (b) a first photosensitive material region (e.g., comprising PI or POB) in which the upper conductive routing structure 112 is formed, and (c) a second photosensitive material region (e.g., comprising PI or POB) in which the lower conductive routing structure 114 is formed.

As used herein, relative terms such as “upper,” “lower,” “over,” “under,” “face-up,” and “face-down,” for example, describe the relative position or orientation of various elements in the context of the example orientations shown in the various drawings. These relative terms are not intended as fixed or absolute terms, but rather are intended to encompass other orientations of the relevant structures (e.g., other orientations of electronic package 100) in addition to those shown in the drawings. The illustrated orientations of the various structures shown in the accompanying drawings, including electronic package 100 shown in FIGS. 1A-1B, are arbitrary; the electronic package 100 and other illustrated structures may be rotated or otherwise oriented in any other way (with corresponding adjustment of any relative terms used herein, e.g., “upper,” “lower,” “over,” “under,” “face-up,” and “face-down”), without departing from the scope of the present disclosure. For example, electronic package 100 may be oriented upside-down relative to the orientation shown in FIGS. 1A-1B, or may be oriented vertically (as opposed to horizontally as shown in FIGS. 1A-1B), for example by rotating the electronic package 100 by 90 degrees (or other angular rotation) about either the x-axis or y-axis shown in FIG. 1A.

In some examples, the electronic package 100 may be a panel level package (PLP), e.g., wherein multiple instances of the electronic package 100 or similar electronic packages may be formed on a common panel.

In some examples, the first IC die 102 and second IC die 104 comprise respective Metal Oxide Silicon Field Effect Transistor (MOSFET) dies, for example vertical MOSFET dies. In one example, the first IC die 102 comprises a first silicon carbide (SiC) MOSFET, and the second IC die 104 comprises a second SiC MOSFET.

In some examples, the first IC die 102 in the first orientation is a first MOSFET die arranged in a “face-up” orientation with (a) a first MOSFET gate connection pad 120 and a first MOSFET source connection pad 122 on an upper side of the first MOSFET die 102, and (b) a first MOSFET drain connection pad 124 on a lower side of the first MOSFET die 102, and the second IC die 104 arranged in the second orientation is a second MOSFET die arranged in a “face-down” orientation with (a) a second MOSFET drain connection pad 130 on an upper side of the second MOSFET die 104 and (b) a second MOSFET gate connection pad 132 and a second MOSFET source connection pad 134 on a lower side of the second MOSFET die 104. In some examples first MOSFET die 102 and second MOSFET die 104 are identical type parts, with second MOSFET die 104 flipped over in relation to first MOSFET die 102.

The first MOSFET gate connection pad 120, the first MOSFET source connection pad 122, the first MOSFET drain connection pad 124, the second MOSFET drain connection pad 130, the second MOSFET gate connection pad 132, and the second MOSFET source connection pad 134 may comprise respective solder pads (or alternatively, sintered paste) formed on the first IC die 102 and second IC die 104, respectively. In some examples, respective connection pads 120, 122, 124, 130, 132, and 134 may be formed on aluminum on the respective upper and lower sides of the first IC die 102 and second IC die 104.

In other examples, the first IC die 102 and second IC die 104 may be inverted relative to the orientation shown in FIG. 1B; thus, the first IC die 102 may be arranged in a face-down orientation and the second IC die 104 may be arranged in a face-up orientation.

The upper conductive routing structure 112 extending over the first IC die 102 and second IC die 104 may include one or more conductive layer. For example, as discussed below with reference to FIGS. 2A-2B and FIGS. 3A-3Z, the upper conductive routing structure 112 may include multiple upper conductive routing layers 212 (e.g., multiple RDLs or multiple metal interconnect layers) formed in a stacked manner to define the geometries of the upper conductive routing structure 112. In other examples, the upper conductive routing structure 112 may be formed as a single conductive layer 212 (e.g., a single RDL or single metal interconnect layer)

Similarly, the lower conductive routing structure 114 extending under the first IC die 102 and second IC die 104 may include one or more conductive layer. For example, as discussed below with reference to FIGS. 2A-2B and FIGS. 3A-3Z, the lower conductive routing structure 114 may include multiple lower conductive routing layers 214 (e.g., multiple RDLs or multiple metal interconnect layers) formed in a stacked manner to define the geometries of the lower conductive routing structure 114. In other examples, the lower conductive routing structure 114 may be formed as a single conductive layer 214 (e.g., a single RDL or single metal interconnect layer).

Similarly, the intermediate conductive routing structure 116 between the upper conductive routing structure 112 and lower conductive routing structure 114 may include one or more conductive layer. For example, as discussed below with reference to FIGS. 2A-2B and FIGS. 3A-3Z (in particular, FIGS. 3K-3M), the intermediate conductive routing structure 116 may include one or more vertically-extending contact formed from a single deposited metal layer. In other examples, the intermediate conductive routing structure 116 may include multiple conductive layers formed in a stacked manner to define the geometries of the intermediate conductive routing structure 116.

In some examples, one or more of the upper conductive routing structure 112, the lower conductive routing structure 114, and the intermediate conductive routing structure 116 comprise electroplated copper or other deposited conductor, e.g., sputtered gold or aluminum. In some examples at least one of the upper conductive routing structure 112 or the lower conductive routing structure 114 comprises a leadframe, e.g., a copper leadframe, e.g., for use in certain high current applications.

In some examples, the conductive routing structure 110 (including elements of the upper conductive routing structure 112, lower conductive routing structure 114, and intermediate conductive routing structure 116) may define:
(a) a first MOSFET gate contact 140 connected to the first MOSFET gate connection pad 120 on the upper side of the first MOSFET die 102,
(b) a ground terminal 142 connected to the first MOSFET source connection pad 122 on the upper side of the first MOSFET die 102,
(c) a high voltage terminal 144 connected to the second MOSFET drain connection pad 130 on the upper side of the second MOSFET die 104,
(d) a second MOSFET gate contact 146 connected to the second MOSFET gate connection pad 132 on the lower side of the second MOSFET die 104, and
(e) an output terminal 150 connected to (i) the first MOSFET drain connection pad 124 on the lower side of the first MOSFET die 102 and (ii) the second MOSFET source connection pad 134 on the lower side of the second MOSFET die 104.

In the example shown in FIGS. 1A and 1B, the first MOSFET gate contact 140, the ground terminal 142, and the high voltage terminal 144 comprise respective elements of the upper conductive routing structure 112; and the second MOSFET gate contact 146 and the output terminal 150 comprise respective elements of the upper conductive routing structure 112, the intermediate conductive routing structure 116, and the lower conductive routing structure 114.

As shown, the first MOSFET gate contact 140, the ground terminal 142, the high voltage terminal 144, the second MOSFET gate contact 146, and the output terminal 150 may be exposed on an upper side 160 of the electronic package 100, e.g., allowing electrical connections between the respective contacts 140, 142, 144, 146, and 150 and respective electronics provided on a PCB or other substrate or device to which the upper side 160 of the electronic package 100 is mounted. The output terminal 150 may also be exposed on a lower side 162 of the electronic package 100, e.g., for connection to a busbar.

The example electronic package 100 may include other dies not shown in FIGS. 1A and 1B, for example one or more gate drivers, resistors, and capacitors.

In some examples, the example electronic package 100 may exhibit a reduced inductance, as compared with certain conventional packages (e.g., conventional packaging including various traces or bond wires, without limitation, in the respective gate drive control loop that define resonant tanks (LC tanks). For example, the electronic package 100 may exhibit a total inductance of less than 2 nanoHenry (nH).

FIGS. 2A and 2B show an example electronic device 200 including an example double-sided electronic package 201 (or simply electronic package 201, for convenience), a device substrate 236, and a busbar 238. In particular, FIG. 2A shows a top view of the example electronic device 200, and FIG. 2B shows a cross-sectional side view through line 2B-2B shown in FIG. 2A.

As shown, an upper side 260 of the electronic package 201 may be mounted or otherwise secured to the device substrate 236, e.g., a PCB, interposer, or other electronic device, and the busbar 238 may be mounted or otherwise secured to a lower side 262 of the electronic package 201.

The example electronic package 201 may include three first IC dies 202 arranged in a first orientation and three second IC dies 204 arranged in a second orientation inverted relative to the first orientation. (In an alternative example, a similar electronic package may be formed with four IC dies per switch).

The electronic package 201 may also include a conductive routing structure 210 including (a) an upper conductive routing structure 212 extending over the first IC dies 202 and second IC dies 204, (b) a lower conductive routing structure 214 extending under the first IC dies 202 and second IC dies 204, and (c) an intermediate conductive routing structure 216 between the upper conductive routing structure 212 and lower conductive routing structure 214, e.g., to connect respective elements of the upper conductive routing structure 212 with respective elements of the lower conductive routing structure 214.

An encapsulation structure 218 at least partially encapsulates the first IC dies 202 and second IC dies 204. The encapsulation structure 218 may include one or multiple encapsulation regions, e.g., comprising an epoxy or other mold compound, a photosensitive material (e.g., polyimide (PI) or polyphenylene ester (POB)), or other insulating material or materials. In this example, e.g., as shown in FIG. 2B, the encapsulation structure 218 includes (a) a mold compound region 218a (e.g., comprising an epoxy) formed around the first IC dies 202, second IC dies 204, and intermediate conductive routing structure 216, (b) a first photosensitive material region 218b (e.g., comprising PI or POB) in which the upper conductive routing structure 212 is formed, and (c) a second photosensitive material region 218c (e.g., comprising PI or POB) in which the lower conductive routing structure 214 is formed.

In some examples, the electronic package 201 may be a panel level package (PLP), e.g., wherein multiple instances of the electronic package 201 or similar electronic packages may be formed on a common panel.

In some examples, the first IC dies 202 and second IC dies 204 comprise respective MOSFET dies, for example vertical MOSFETs. In one example, the first IC dies 202 and second IC dies 204 comprise silicon carbide (SiC) MOSFETs.

In this example, the first IC dies 202 are MOSFETs die arranged in a “face-up” orientation, with respective first IC dies 202 having (a) a respective first MOSFET gate connection pad 220 and a respective first MOSFET source connection pad 222 on an upper side of the respective first MOSFET die 202, and (b) a respective first MOSFET drain connection pad 224 on a lower side of the respective first MOSFET die 202. In contrast, the second IC dies 204 are MOSFET dies arranged in a “face-down” orientation, with respective second IC dies 204 having (a) a respective second MOSFET drain connection pad 230 on an upper side of the respective second MOSFET die 204 and (b) a respective second MOSFET gate connection pad 232 and a respective second MOSFET source connection pad 234 on a lower side of the respective second MOSFET die 204.

The respective first MOSFET gate connection pads 220, first MOSFET source connection pads 222, first MOSFET drain connection pads 224, second MOSFET drain connection pads 230, second MOSFET gate connection pads 232, and second MOSFET source connection pads 234 may comprise respective solder pads (or alternatively, sintered paste) formed on the first IC dies 202 and second IC dies 204, respectively. In some examples, respective connection pads 220, 222, 224, 230, 232, and 234 may be formed on aluminum on the respective upper and lower sides of the respective first IC dies 202 and second IC dies 204.

In other examples, the first IC dies 202 and second IC dies 204 may be inverted relative to the orientation shown in FIG. 2B; thus, the first IC dies 202 may be arranged in a face-down orientation and the second IC dies 204 may be arranged in a face-up orientation.

As best shown in FIG. 2B, the upper conductive routing structure 212 extending over the first IC dies 202 and second IC dies 204 may include multiple upper conductive routing layers 270, in this example four metal layers, and the lower conductive routing structure 214 extending under the first IC dies 202 and second IC dies 204 may similarly include multiple lower conductive routing layers 272, in this example four metal layers. The upper conductive routing layers 270 may comprise respective RDLs and/or respective metal interconnect layers formed in a stacked manner to define the geometries of the upper conductive routing structure 212. Similarly, the lower conductive routing layers 272 may comprise respective RDLs and/or respective metal interconnect layers formed in a stacked manner to define the geometries of the lower conductive routing structure 214. In some examples, the multiple upper conductive routing layers 270 and multiple lower conductive routing layers 272 may be formed by electrochemical deposition (electroplating) of copper or deposition of other metal(s), e.g., sputtered gold or aluminum, as discussed below with reference to the method shown in FIGS. 3A-3Z. In some examples, one or more upper conductive routing layer 270 or lower conductive routing layer 272 may comprise a leadframe, e.g., a copper leadframe.

In this example, the intermediate conductive routing structure 216 between the upper conductive routing structure 212 and lower conductive routing structure 214 is formed as a single conductive layer, e.g., by electrochemical deposition of copper or other metal, as discussed below with reference to FIG. 3L. In other examples, the intermediate conductive routing structure 216 may include multiple conductive layers (e.g., multiple RDLs and/or metal interconnect layers) formed in a stacked manner to define the geometries of the intermediate conductive routing structure 216.

As shown in FIGS. 2A-2B, the conductive routing structure 210 (including elements of the upper conductive routing structure 212, lower conductive routing structure 214, and intermediate conductive routing structure 216) defines:
(a) a first MOSFET gate contact 240 connected to the respective first MOSFET gate connection pads 220 on the respective upper sides of the three first MOSFET dies 202,
(b) a ground terminal 242 connected to the respective first MOSFET source connection pads 222 on the respective upper sides of the three first MOSFET dies 202,
(c) a high voltage terminal 244 connected to the respective second MOSFET drain connection pads 230 on the respective upper sides of the three second MOSFET dies 204,
(d) a second MOSFET gate contact 246 connected to the respective second MOSFET gate connection pads 232 on the respective lower sides of the three second MOSFET dies 204, and
(e) an output terminal 250 connected to (i) the respective first MOSFET drain connection pads 224 on the respective lower sides of the three first MOSFET dies 202 and (ii) the respective second MOSFET source connection pads 234 on the respective lower sides of the three second MOSFET dies 204.

As shown, the first MOSFET gate contact 240, the ground terminal 242, and the high voltage terminal 244 comprise respective elements of the upper conductive routing structure 212; and the second MOSFET gate contact 246 and the output terminal 250 comprise respective elements of the upper conductive routing structure 212, the intermediate conductive routing structure 216, and the lower conductive routing structure 214.

The first MOSFET gate contact 240, ground terminal 242, high voltage terminal 244, second MOSFET gate contact 246, and output terminal 250 respectively include elements of multiple conductive routing layers (e.g., multiple copper layers). Accordingly, contacts and terminals 240, 242, 244, 246, and 250 may be referred to as multi-layer contacts/terminals 240, 242, 244, 246, and 250.

As shown, the first MOSFET gate contact 240, the ground terminal 242, the high voltage terminal 244, the second MOSFET gate contact 246, and the output terminal 250 include exposed upper surfaces (exposed through the first photosensitive material region 218b) on the upper side 260 of the electronic package 201, providing electrical connections between the respective contacts 240, 242, 244, 246, and 250 and respective electronics provided on the device substrate (e.g., PCB) 236. The output terminal 250 includes an exposed lower surface (exposed through the second photosensitive material region 218c) on the lower side 262 of the electronic package 201, providing an electrical connection to the busbar 238.

In this example, the second MOSFET gate contact 246 and the output terminal 250 utilize respective elements of the intermediate conductive routing structure 216 to provide electrical connections between the lower sides of the first and second IC dies 202, 204 and respective electronics provided on the device substrate 236 on the upper side 260 of the electronic package 201.

The example electronic package 201 may include other dies not shown in FIGS. 2A and 2B, for example one or more gate drivers, resistors, and capacitors.

In some examples, the example electronic package 201 may exhibit a reduced inductance, as compared with certain conventional packages (e.g., conventional packaging including various traces, or bond wires, without limitation, in the respective gate drive control loop that define resonant tanks (LC tanks). For example, the electronic package 201 may exhibit a total inductance of less than 2 nanoHenry (nH).

FIGS. 3A-3Z are a series of cross-sectional side views showing an example method of forming an example double-sided electronic package 400 (or simply electronic package 400, for convenience) including conductive routing layers above and below a pair of IC dies arranged inverted relative to each other, e.g., similar to the example double-sided electronic package 100, or double-sided electronic package 201, shown in FIGS. 1A-1B and FIGS. 2A-2B discussed above. The completed double-sided electronic package 400 is shown in FIG. 3Z, discussed below.

As shown in FIG. 3A, a wafer 300 (e.g., comprising silicon or silicon carbide) is formed with elements of multiple MOSFET dies, including respective doped regions (e.g., defining respective source, drain, and gate regions) and bond pads 302 (e.g., aluminum bond pads) on an upper side of the wafer 300. The bond pads 302 may include respective gate connection bond pads 302a and source connection bond pads 302b.

As shown in FIG. 3B, a copper seed layer 304 is formed (e.g., by PVD deposition) on the respective bond pads 302a, 302b.

As shown in FIG. 3C, a layer of photoresist is deposited, patterned and etched to form a patterned photoresist 306 defining respective photoresist openings 308 aligned over respective bond pads 302a, 302b having the copper seed layer 304 formed thereon.

As shown in FIG. 3D, a copper routing layer 310 is deposited (e.g., by electrochemical deposition process) in the respective photoresist openings 308 and attaches to the copper seed layer 304 on the respective bond pads 302a, 302b, to form respective gate contact elements 312 over respective gate connection bond pads 302a and respective source contact elements 314 over respective source connection bond pads 302b.

As shown in FIG. 3E, remaining portions of the patterned photoresist 306 may be removed.

As shown in FIG. 3F, the wafer 300 may be flipped over such that the back side (MOSFET drain region) is facing upwards, and the wafer 300 is back-grinded to a desired thickness for the IC dies 324 being formed (see FIG. 3I).

As shown in FIG. 3G, a thin seed layer 316 of titanium copper (TiCu) is deposited (e.g., sputtered) on the back side of the wafer 300.

As shown in FIG. 3H, a copper routing layer 318 is deposited (e.g., by electrochemical deposition process) and attaches to the TiCu seed layer 316 to form a drain contact layer 320 over the drain regions of the respective MOSFETs.

As shown in FIG. 3I, the wafer 300 may be cut (or diced) to define multiple singulated MOSFET dies 324, with respective MOSFET dies 324 having a respective gate contact element 312, a respective source contact element 314, and a respective drain contact element 322 defined by a respective portion of the drain contact layer 320. The singulated MOSFET dies 324 may subsequently be mounted on a carrier, as discussed below with reference to FIG. 3N.

As shown in FIG. 3J, a thermal release layer 330 is deposited on a carrier 332 (e.g., a rigid panel comprising an epoxy or metal).

As shown in FIG. 3K, a thick layer of photoresist (e.g. having a thickness greater than a thickness of the singulated MOSFET dies 324 discussed above) is deposited, patterned and etched to form a patterned photoresist 334 including slot openings 336a and 336b extending down to the thermal release layer 330.

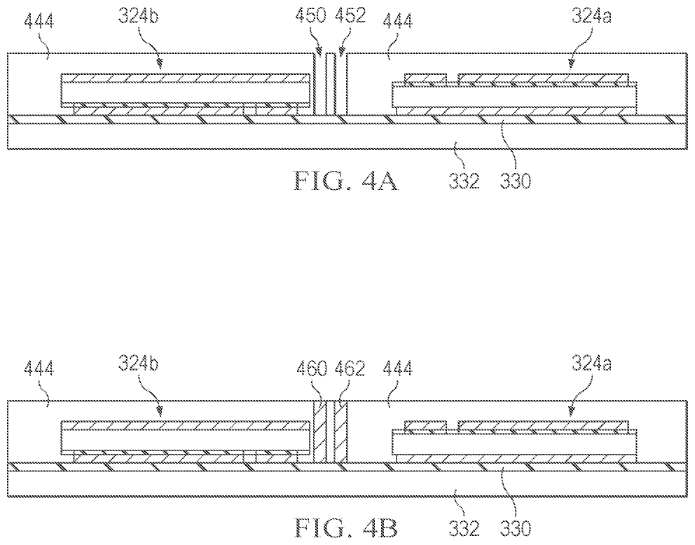

As shown in FIG. 3L, vertically-extending contacts 340 and 342 are formed in the slot openings 336a and 336b, respectively, e.g., by sputtering a thin copper seed layer followed by deposition of a thick copper layer by electrochemical deposition. In other examples, vertically-extending contacts 340 and 342 may be formed by a different process, e.g., by forming a mold encapsulation over the MOSFET dies 324a and 324b, etching vertically-extending slot openings in the mold encapsulation, and filling the slot openings with copper or other conductive material, for example as shown in FIGS. 4A-4B discussed below.

As shown in FIG. 3M, remaining portions of the patterned photoresist 334 may be removed, leaving the vertically-extending contacts 340 and 342 extending upwardly from the thermal release layer 330 on the carrier 332.

As shown in FIG. 3N, multiple singulated MOSFET dies 324, including a first MOSFET die 324a and a second MOSFET die 324b, are mounted on the thermal release layer 330 on the carrier 332, laterally spaced apart from each other and from the vertically-extending contacts 340 and 342. The first MOSFET die 324a is mounted in a first orientation (face-up orientation) with a first side facing upwardly and a second side facing downwardly, and the second MOSFET die 324b is mounted in a second orientation (face-down orientation) with a first side facing downwardly and a second side facing upwardly, i.e., inverted relative to the first orientation (face-up orientation) of the first MOSFET die 324a.

In the face-up orientation of the first MOSFET die 324a, the drain contact element 322 (adjacent the MOSFET drain) on the second side of the first MOSFET die 324a faces downwardly (mounted to the thermal release layer 330), and the gate contact element 312 and source contact element 314 (adjacent the MOSFET gate and source, respectively) on the first side of the first MOSFET die 324a face upwardly away from the thermal release layer 330. In contrast, in the face-down orientation of the second MOSFET die 324b, the gate contact element 312 and source contact element 314 (adjacent the MOSFET gate and source, respectively) on the first side of the second MOSFET die 324b face downwardly (mounted to the thermal release layer 330), and the drain contact element 322 (adjacent the MOSFET drain) on the second side of the second MOSFET die 324b faces upwardly away from the thermal release layer 330.

As shown in FIG. 3O, a mold encapsulation 344 is formed over the MOSFET dies 324a and 324b and vertically-extending contacts 340 and 342. The mold encapsulation 344 may comprise an epoxy or other suitable mold compound.

As shown in FIG. 3P, a planarization process (e.g., a grinding process) is performed to remove an upper portion of the mold encapsulation 344 to expose the gate contact element 312 and source contact element 314 of the first MOSFET die 324a, the drain contact element 322 of the second MOSFET die 324b, and top surfaces of the vertically-extending contacts 340 and 342.

A series of conductive routing layers are deposited over the planarized structure to form various multi-layer contacts or terminals (or respective portions thereof), as shown in FIGS. 3Q-3V.

As shown in FIG. 3Q, a photo-sensitive layer 350 is deposited on the planarized structure by a coating process. In some examples, the photo-sensitive layer 350 may comprise polyimide (PI) or polyphenylene ester (POB).

As shown in FIG. 3R, the photo-sensitive layer 350 may be patterned (e.g., by selectively exposing, developing, and cleaning the photo-sensitive layer 350) to define respective photo-sensitive layer openings 352 exposing upper surfaces of the gate contact element 312 of the first MOSFET die 324a, source contact element 314 of the first MOSFET die 324a, drain contact element 322 of the second MOSFET die 324b, and vertically-extending contacts 340 and 342.

As shown in FIG. 3S, a copper routing layer is deposited (e.g., by electrochemical deposition process) in the respective photo-sensitive layer openings 352 to form respective contact elements 356 in contact with the gate contact element 312 of the first MOSFET die 324a, source contact element 314 of the first MOSFET die 324a, drain contact element 322 of the second MOSFET die 324b, and vertically-extending contacts 340 and 342. The patterned photo-sensitive layer 350 may remain intact, forming part of the mold encapsulation of the resulting electronic package.

The process shown in FIGS. 3Q-3S may then be repeated any number of times, e.g., as shown in FIGS. 3T-3Z discussed below, to create additional copper routing layers with respective contact elements to form respective multi-layer contacts and terminals (e.g., corresponding with the multi-layer contacts/terminals 240, 242, 244, 246, and 250 shown in FIG. 2B discussed above).

As shown in FIG. 3T, a photo-sensitive layer 360 (e.g., comprising PI or POB) is deposited and patterned (e.g., by selectively exposing, developing, and cleaning the photo-sensitive layer 360) to define respective photo-sensitive layer openings 362 exposing upper surfaces of the contact elements 356.

As shown in FIG. 3U, a copper routing layer is deposited (e.g., by electrochemical deposition process) in the respective photo-sensitive layer openings 362 to form respective contact elements 366 in contact with respective contact elements 356. The patterned photo-sensitive layer 360 may remain intact, forming part of the mold encapsulation of the resulting electronic package.

As shown in FIG. 3V, another layer of contact elements 370, in contact with respective contact elements 366, may be similarly formed in a respective patterned photo-sensitive layer 372, which may also remain intact, forming part of the mold encapsulation of the resulting electronic package.

As shown in FIG. 3W, the structure may be flipped over, and the carrier 332 and thermal release layer 330 removed (e.g., by a thermal release or mechanical release process), thereby exposing upper surfaces of the drain contact element 322 of the first MOSFET die 324a, the gate contact element 312 and source contact element 314 of the second MOSFET die 324b, and upper surfaces of the vertically-extending contacts 340 and 342.

A series of conductive routing layers are deposited over the structure shown in FIG. 3W to form various multi-layer contacts or terminals (or respective portions thereof), as shown in FIGS. 3X-3Z.

As shown in FIG. 3X, a layer of contact elements 380, in contact with respective contact elements 312, 314, 322, 340, and 342 shown in FIG. 3W, may be similarly formed in a patterned photo-sensitive layer 382, according to the process described above with respect to FIGS. 3Q-3S. The patterned photo-sensitive layer 382 may remain intact, forming part of the mold encapsulation of the resulting electronic package.

Similarly, as shown in FIG. 3Y, another layer of contact elements 386, in contact with respective contact elements 380, may be formed in a respective patterned photo-sensitive layer 388, which may remain intact, forming part of the mold encapsulation of the resulting electronic package.

Similarly, as shown in FIG. 3Z, another layer of contact elements 390, in contact with respective contact elements 386, may be formed in a respective patterned photo-sensitive layer 392, which may remain intact, forming part of the mold encapsulation of the resulting electronic package.

The resulting structure shown in FIG. 3Z defines the example double-sided electronic package 400. The example double-sided electronic package 400 includes a conductive routing structure 402 defined by the various contact elements formed on and around the first and second MOSFET dies 324a and 324b, including contact elements 312, 314, 322, 340, 342, 356, 366, 370, 380, 386 formed in multiple routing layers as discussed above. Respective elements of the conductive routing structure 402 define various multi-layer contacts and terminals, including (a) a multi-layer first MOSFET gate contact 404 connected to the gate of the first MOSFET die 324a, (b) a multi-layer ground terminal 406 connected to the source of the first MOSFET die 324a, (c) a multi-layer high voltage terminal 408 connected to the drain of the second MOSFET die 324b, (d) a multi-layer second MOSFET gate contact 410 connected to the gate of the second MOSFET die 324b, and (e) a multi-layer output terminal 412 connected to (i) the drain of the first MOSFET die 324a and (ii) the source of the second MOSFET die 324b.

The MOSFET dies 324a and 324b and the various multi-layer contacts and terminals 404, 406, 408, 410, and 412 defined by the conductive routing structure 402 are at least partially encapsulated by an encapsulation structure 416 defined collectively by the mold encapsulation 344 (e.g., comprising epoxy) and the photo-sensitive layers 350, 360, 372, 382, 388, and 392 (e.g., comprising PI or POB).

As noted above, in other examples the vertically-extending contacts 340 and 342 may be formed by an alternative process. FIGS. 4A and 4B illustrate one alternative process for forming vertically-extending contacts 340 and 342. As shown in FIG. 4A, after mounting the MOSFET dies 324a and 324b on the carrier 332, a mold encapsulation 444 may be formed over the MOSFET dies 324a and 324b, and vertically-extending slot openings 450 and 452 may be etched in the mold encapsulation 444, e.g., extending down to the thermal release layer 330. As shown in FIG. 4B, copper may be deposited (e.g., by electrochemical deposition) in the vertically-extending slot openings 450 and 452 to form vertically-extending contacts 460 and 460.

In other examples, vertically-extending contacts may be formed by placing conductive shunts or other passive elements on the carrier 332.

Although example embodiments have been described above, other variations and embodiments may be made from this disclosure without departing from the spirit and scope of these embodiments.

1. An electronic package, comprising:
a first integrated circuit (IC) die arranged in a first orientation;
a second IC die arranged in a second orientation inverted relative to the first orientation;
an upper conductive routing structure extending over the first IC die and second IC die;
a lower conductive routing structure extending under the first IC die and second IC die; and
an encapsulation structure at least partially encapsulating the first IC die and the second IC die.

2. The electronic package of claim 1, wherein the electronic package comprises a panel level package (PLP).

3. The electronic package of claim 1, wherein:
the first IC die arranged in the first orientation comprises a first Metal Oxide Silicon Field Effect Transistor (MOSFET) die arranged with (a) a first MOSFET gate connection pad and a first MOSFET source connection pad on an upper side of the first MOSFET die, and (b) a first MOSFET drain connection pad on a lower side of the first MOSFET die; and
the second IC die arranged in the second orientation comprises a second MOSFET die arranged with (a) a second MOSFET drain connection pad on an upper side of the second MOSFET die and (b) a second MOSFET gate connection pad and a second MOSFET source connection pad on a lower side of the second MOSFET die.

4. The electronic package of claim 3, wherein:
the upper conductive routing structure defines (a) a high voltage terminal connected to the second MOSFET drain connection pad and (b) a ground terminal connected to the first MOSFET source connection pad; and
the lower conductive routing structure defines an output terminal connected to (a) the first MOSFET drain connection pad and (b) the second MOSFET source connection pad.

5. The electronic package of claim 3, wherein the first IC die comprises a first silicon carbide (SiC) MOSFET, and the second IC die comprises a second SiC MOSFET.

6. The electronic package of claim 1, wherein at least one of the upper conductive routing structure or the lower conductive routing structure comprises a redistribution layer (RDL).

7. The electronic package of claim 1, wherein:
the upper conductive routing structure comprises multiple stacked upper redistribution layers (RDLs); and
the lower conductive routing structure comprises multiple stacked lower RDLs.

8. The electronic package of claim 1, wherein at least one of the upper conductive routing structure or the lower conductive routing structure comprises a leadframe.

9. The electronic package of claim 1, comprising:
a third integrated circuit (IC) die arranged in the first orientation; and
a fourth IC die arranged in the second orientation inverted relative to the first orientation;
wherein the upper conductive routing structure extends over the first IC die, second IC die, third IC die, and fourth IC die; and
wherein the lower conductive routing structure extends under the first IC die, second IC die, third IC die, and fourth IC die.

10. An electronic device, comprising:
an electronic package, comprising:
a plurality of first Metal Oxide Silicon Field Effect Transistor (MOSFET) dies arranged in a first orientation;
a plurality of second MOSFET dies arranged in a second orientation inverted relative to the first orientation;
a first conductive routing structure including at least one first conductive routing layer extending over the plurality of first MOSFET dies and over the plurality of second MOSFET dies, the first conductive routing structure defining:
a first MOSFET drain connection structure connected to respective drain connection pads on the plurality of first MOSFET dies;
a second MOSFET source connection structure connected to respective source connection pads on the plurality of second MOSFET dies; and
a second MOSFET gate connection structure connected to respective gate connection pads on the plurality of second MOSFET dies; and
a second conductive routing structure including at least one second conductive routing layer extending under the plurality of first MOSFET dies and under the plurality of second MOSFET dies, the second conductive routing structure defining:
a second MOSFET drain connection structure connected to respective drain connection pads on the plurality of second MOSFET dies; and
a first MOSFET source connection structure connected to respective source connection pads on the plurality of first MOSFET dies.

11. The electronic device of claim 10, the electronic package comprising an encapsulation structure at least partially encapsulating the plurality of first MOSFET dies, the plurality of second MOSFET dies, the first conductive routing structure, and the second conductive routing structure.

12. The electronic device of claim 10, the electronic package comprising a first MOSFET gate connection structure connected to respective gate connection pads on the plurality of first MOSFET dies, the first MOSFET gate connection structure including at least one conductive element formed in the first conductive routing structure and at least one conductive element formed in the second conductive routing structure.

13. The electronic device of claim 10, comprising a busbar connected to the second MOSFET source connection structure and the first MOSFET drain connection structure.

14. The electronic device of claim 10, comprising a printed circuit board;
wherein the second MOSFET drain connection structure and the first MOSFET source connection structure are mounted to respective electronics on the printed circuit board.

15. The electronic device of claim 10, comprising a printed circuit board;
wherein the second MOSFET source connection structure, the first MOSFET drain connection structure, the first MOSFET gate connection structure, and the second MOSFET gate connection structure are mounted to respective electronics on the printed circuit board.

16. A method, comprising:
forming a thermal release layer on a carrier;
arranging a first IC die and a second IC die on the thermal release layer, the first IC die arranged in a first orientation, and the second IC die arranged in a second orientation inverted relative to the first orientation, wherein a first side of the first IC die and a second side of the second IC die face the carrier, and a second side of the first IC die and a first side of the second IC die face away from the carrier;
forming a mold encapsulation over the first IC die and second IC die;
forming a first conductive routing structure over the second side of the first IC die and the first side of the second IC die, the first conductive routing structure defining first conductive connections to respective contacts on the second side of the first IC die and the first side of the second IC die;
removing the carrier;
forming a second conductive routing structure on the first side of the first IC die and the second side of the second IC die, the second conductive routing structure defining second conductive connections to respective contacts on the first side of the first IC die and the second side of the second IC die.

17. The method of claim 16, comprising:
forming a first contact element on the first IC die prior to arranging the first IC die on the thermal release layer;
wherein arranging the first IC die on the thermal release layer comprises arranging the first IC die with the first contact element facing the thermal release layer.

18. The method of claim 16, comprising:
forming a first contact element on the first IC die prior to arranging the first IC die on the thermal release layer;
wherein forming the first conductive routing structure comprises forming at least one first conductive routing element in contact with the first contact element on the first IC die.

19. The method of claim 16, comprising:
forming a vertically-extending contact extending upwardly from the thermal release layer;
wherein forming the second conductive routing structure includes forming a conductive connection between the vertically-extending contact and a respective contact on the first side of the first IC die.

20. The method of claim 19, comprising forming the vertically-extending contact extending upwardly from the thermal release layer prior to arranging the first IC die and the second IC die on the thermal release layer.

21. The method of claim 16, comprising:
forming a first vertically-extending contact and a second vertically-extending contact extending upwardly from the thermal release layer;
wherein forming the second conductive routing structure includes forming (a) a first conductive connection between the first vertically-extending contact and a respective contact on the first side of the first IC die and (b) a second conductive connection between the second vertically-extending contact and a respective contact on the second side of the second IC die.

22. The method of claim 16, wherein:
the first IC die comprises a first MOSFET die;
the second IC die comprises a second MOSFET die;
arranging the first IC die and the second IC die on the thermal release layer comprises:
arranging the first IC die with (a) a first MOSFET gate connection pad and a first MOSFET source connection pad on the second side of the first IC die facing away from the carrier, and (b) a first MOSFET drain connection pad on the first side of the first IC die facing the carrier; and
arranging the second IC die with (a) a second drain connection pad on the first side of the second IC die facing away from the carrier and (b) a second gate connection pad and a second source connection pad on the second side of the second IC die facing the carrier.

23. The method of claim 16, wherein forming the first conductive routing structure or forming the second conductive routing structure comprises forming a stack of multiple redistribution layers (RDLs).
